(19) United States
(12) Patent Application Publication
(10) Pub. No.: US 2012/0033363 A1
(43) Pub. Date: Feb. 9, 2012

(54) FLAT ELECTRONIC DEVICE

(75) Inventor: WANG-HUNG YEH, Taoyuan (TW)

(73) Assignee: HON HAI PRECISION INDUSTRY CO., LTD., Tu-Cheng (TW)

(21) Appl. No.: 13/086,196

(22) Filed: Apr. 13, 2011

(30) Foreign Application Priority Data
Aug. 5, 2010 (TW) 99126152

(51) Int. Cl. H05K 7/00

(52) U.S. Cl. 361/679.01

(57) ABSTRACT

A flat electronic device includes a main body with a display screen, a support stand, and a rotation mechanism. The support stand is used for supporting the main body. The rotation mechanism pivotally connects the main body and the support stand. The support stand further includes a battery for powering the main body and a connecting portion connecting the battery and the rotation mechanism.

### BACKGROUND

1. Technical Field

The present disclosure relates to electronic devices, and more particularly to a flat electronic device.

2. Description of Related Art

For portability, the volume of a flat electronic device is often small, thus inner space for components thereof is small accordingly. However, a battery, which is often built into the flat electronic device, takes up most of the limited real estate.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout five views.

FIG. 1 is an isometric view of a flat electronic device in accordance with an embodiment.

FIG. 2 is an exploded view of the flat electronic device of FIG. 1.

FIG. 3 is an exploded view of the flat electronic device of FIG. 1 from a reverse direction to FIG. 2.

FIG. 4 is a schematic view of the flat electronic device of FIG. 1 in a first state.

FIG. 5 is a schematic view of the flat electronic device of FIG. 1 in a second state.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

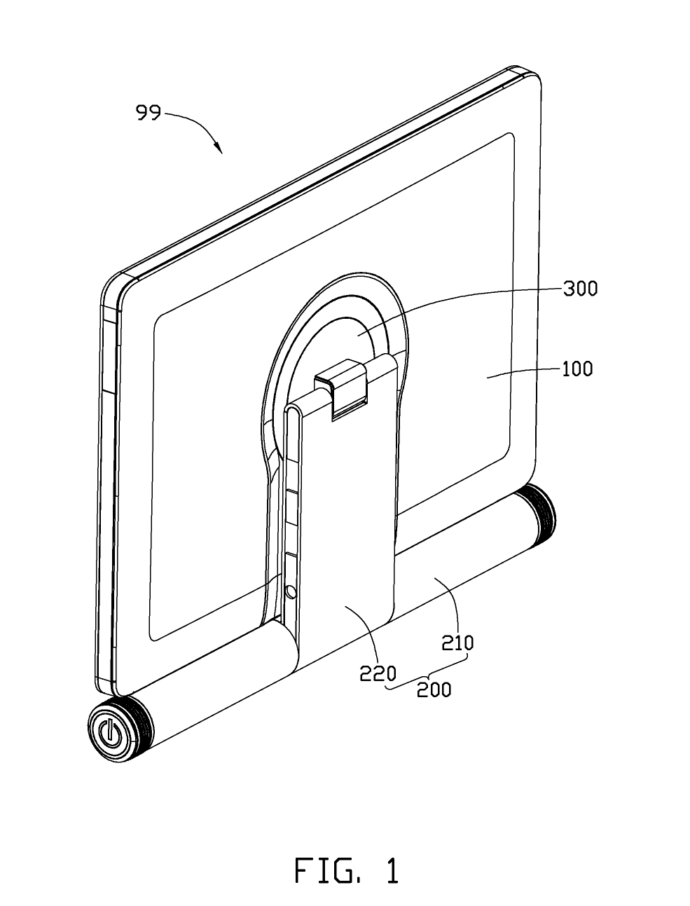

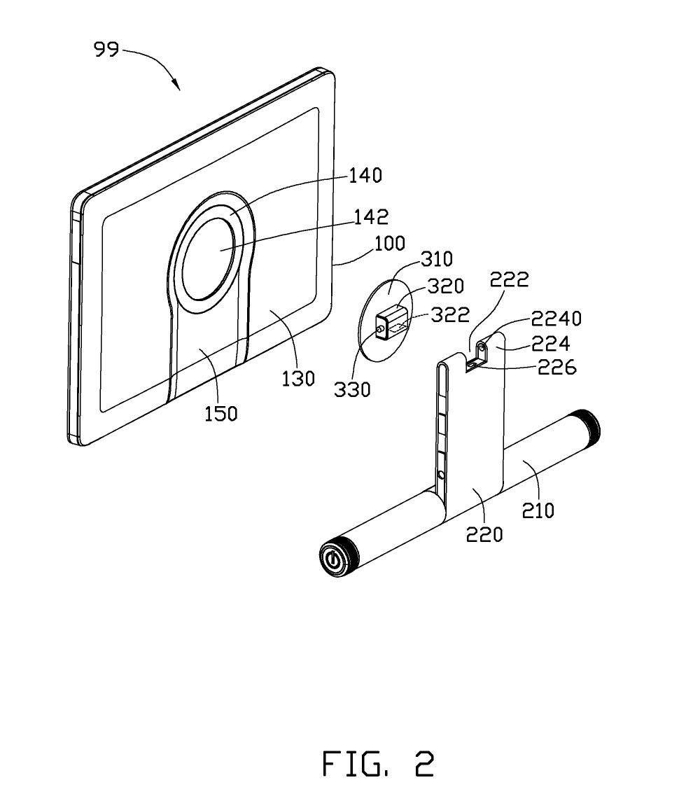

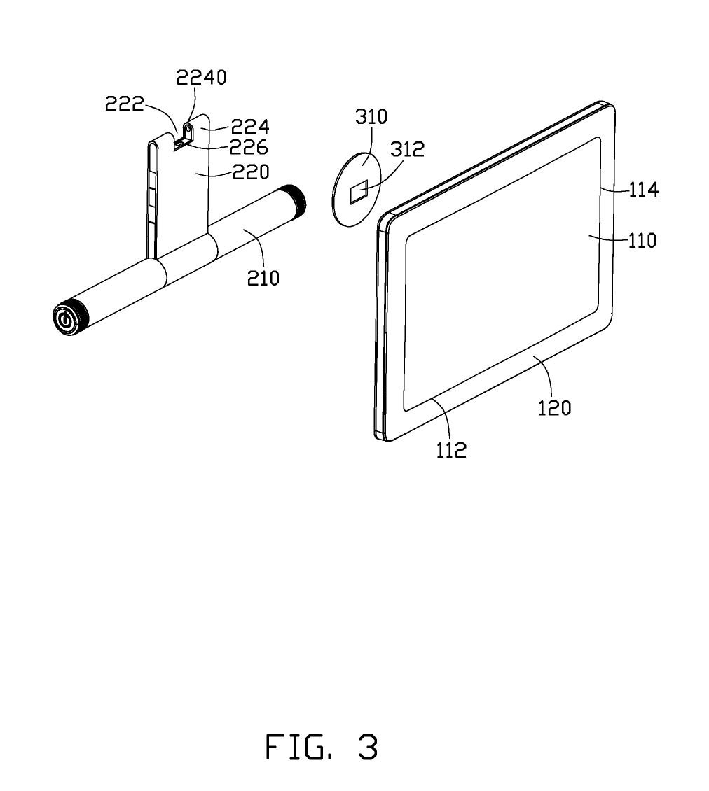

Referring to FIGS. 1-3, a flat electronic device 99 includes a main body 100, a support stand 200 for supporting the main body 100, and a rotation mechanism 300. The rotation mechanism 300 is used for pivotally connecting the main body 100 and the support stand 200 such that the main body 100 is capable of rotating with respect to the support stand 200.

The main body 100 is substantially rectangular. The main body 100 includes a display screen 110, a first surface 120, a second surface 130 opposite to the first surface 120, a positioning portion 140 disposed on the second surface 130, and a receiving portion 150 formed on the second surface 130 and partially recessed inward.

The display screen 110 is disposed on the first surface 120. The display screen 110 includes a first edge 112 and a second edge 114 perpendicular to the first edge 112, and the first edge 112 is longer than the second edge 114.

The positioning portion 140 is in the center of the second surface 130. The positioning portion 140 includes a receiving space 142 on the second surface 130.

The receiving portion 150 is in the middle of the second surface 130, and extends from the positioning portion 140, along the second surface 130, to the side of the first edge 112. The receiving portion 150 communicates with the receiving space 142 of the positioning portion 140.

The support stand 200 includes a cylindrical battery 210 for powering the main body 100, and a connecting portion 220 perpendicularly connected to the middle portion of the battery 210. The battery 210 is adjacent to the main body 100 at the side of the first edge 112. The battery 100 is substantially parallel to the first edge 112 of the display screen 110.

The connecting portion 220 is substantially rectangular, and received in the receiving portion 150. One end of the connecting portion 220 away from the battery 210 is partially cut to form an opening 222, and two connecting members 224 respectively at opposite sides of the opening 222.

The two connecting members 224 respectively define a shaft hole 2240 communicating with the opening 222. The connecting portion 220 further defines a through hole 226 between the connecting members 224 and communicating with the opening 222. The through hole 226 is used for receiving wires electrically connected the battery 210 and the main body 100.

The rotation mechanism 300 includes a circular base portion 310, a rectangular accommodating portion 320 protruding from the base portion 310, and two shafts 330 respectively protruding from opposite sides of the accommodating portion 320. The accommodating portion 320 is received in the opening 222, and the two shafts 330 are respectively inserted into the two shaft holes 2240, thus the main body 100 is capable of rotating through a first angle with respect to the support stand 200 in a first direction. The first angle is between 0 and 180 degrees.

The base portion 310 is rotatably received in the receiving space 142 of the positioning portion 140 such that the main body 100 is capable of rotating through a second angle with respect to the support stand 200 in a second direction. The second direction is perpendicular to the first direction, and the second angle is between 0 and 360 degrees.

The base portion 310 defines an opening 312 communicates with an opening 322 defined in the accommodating portion 320 at the side of the through hole 226, thus the wires can pass through the connecting portion 220 and the rotation mechanism 300 to electrically connect the main body 100 and battery 210.

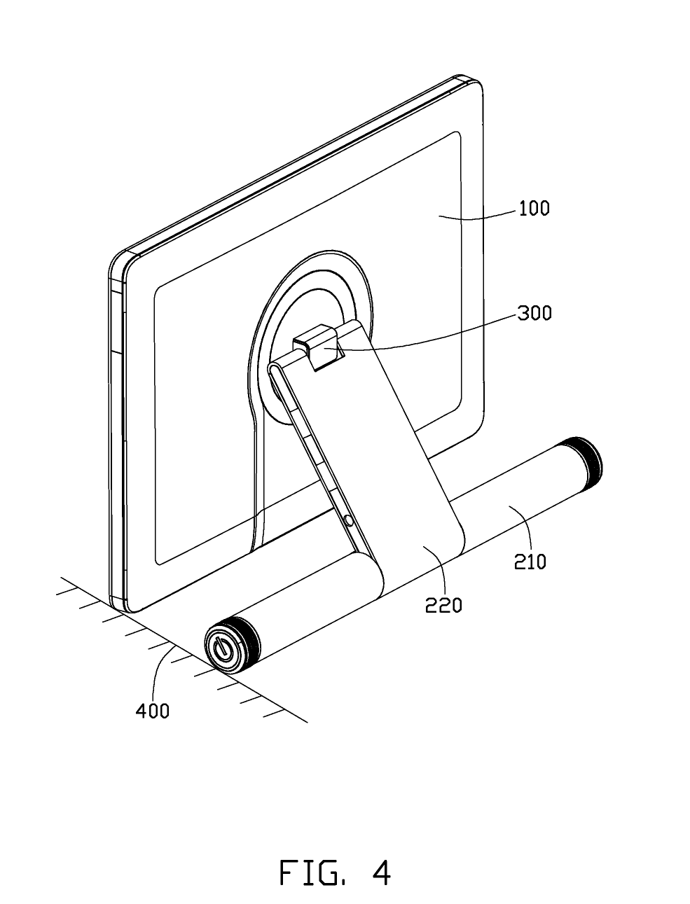

Referring to FIG. 4, when the main body 100 is rotated through the first angle away from the support stand 200 in the first direction, the battery 210 is maintained in parallel with the first edge 112 of the display screen 110. The connecting portion 220 is rotated out of the receiving portion 150. The support stand 200, the main body 100 at the side of the first edge 112 and a flat surface 400 for supporting the flat electronic device 99 combine to form a triangular structure, thus the flat electronic device 99 can stably be mounted on the flat surface 400. Meanwhile, the first angle is capable of being adjusted because of different demands by rotating the main body 100 or the support stand 200.

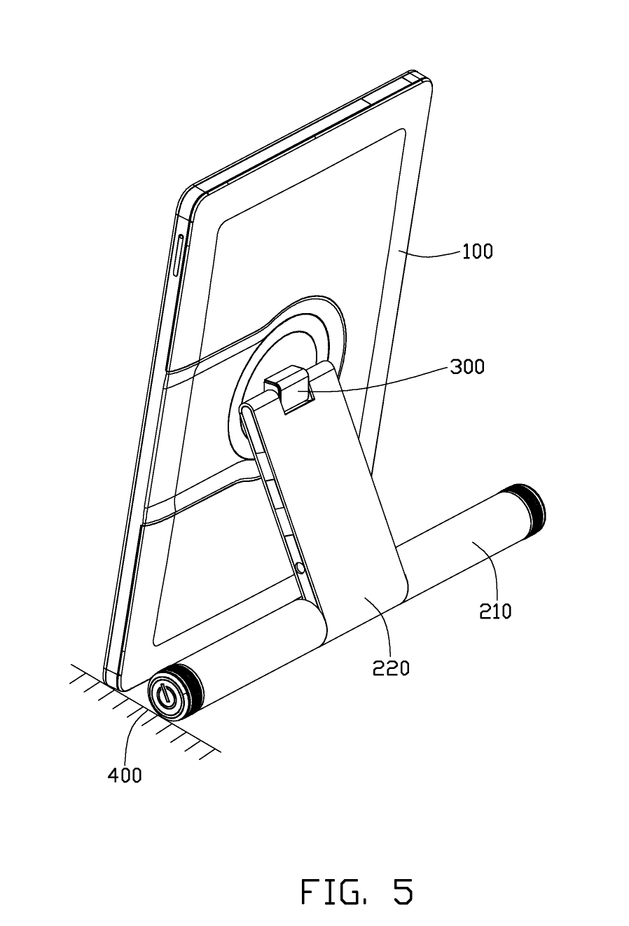

Referring to FIG. 5, the main body 100 shown by FIG. 4 is further rotated through the second angle with respect to the support stand 200 in the second direction. In the embodiment, the second angle is 90 degrees, and the battery 210 is parallel to the second edge 114 of the display screen 110. The support stand 200, the main body 100 at the side of the second edge 112 and the flat surface 400 combine to form a triangular structure, thus the flat electronic device 99 can be stably mounted on the flat surface 400. Meanwhile, the first angle is still capable of being adjusted because of different demands by rotating the main body 100 or the support stand 200.

Furthermore, the battery 210 for powering the main body 100 is built out of the main body 100, thus inner space of the main body 100 can all be used for other electronic components of the flat electronic device 99.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. A flat electronic device, comprising:
a main body with a display screen;
a support stand for supporting the main body; and
a rotation mechanism pivotally connecting the main body and the support stand;
wherein the support stand comprises a battery for powering the main body and a connecting portion connecting the battery and the rotation mechanism.

2. The flat electronic device according to claim 1, wherein the main body is capable of rotating through a first angle with respect to the support stand in a first direction.

3. The flat electronic device according to claim 2, wherein the display screen comprises a first edge and a second edge, lengths of the first and second edges are different, the battery is parallel to the first edge.

4. The flat electronic device according to claim 3, wherein when the main body rotates with respect to the support stand in the first direction, the battery is maintained in parallel with the first edge of the display screen.

5. The flat electronic device according to claim 2, wherein the first angle is between 0 and 180 degrees.

6. The flat electronic device according to claim 2, wherein the main body is further capable of rotating through a second angle with respect to the support stand in a second direction different from the first direction.

7. The flat electronic device according to claim 6, wherein the second direction is perpendicular to the first direction.

8. The flat electronic device according to claim 7, wherein the display screen comprises a first edge and a second edge, and lengths of the first and second edges are different; when the main body rotates with respect to the support stand in the second direction, the battery is capable of switching between parallel with the first edge and parallel with the second edge.

9. The flat electronic device according to claim 6, wherein the second angle is between 0 and 360 degrees.

10. The flat electronic device according to claim 6, wherein the main body comprises a positioning portion; the connecting portion defines at least one shaft hole; the rotation mechanism comprises a base portion, and an accommodating portion protruding from the base portion, and at least one shaft protruding from the accommodating portion; the shaft is inserted into the shaft hole such that the main body is capable of rotating with respect to the support stand in the first direction; and the base portion is rotatably received in the positioning portion such that the main body is capable of rotating with respect to the support stand in the second direction.

11. The flat electronic device according to claim 1, wherein the main body is partially recessed to form a receiving portion for receiving the connecting portion.

12. A flat electronic device, comprising:
a main body with a display screen, the display screen comprising a first edge and a second edge perpendicular to the first edge;
a support stand for supporting the main body, the support stand comprising a battery for powering the main body; and
a rotation mechanism pivotally connecting the main body and the support stand such that the main body is capable of rotating through a first angle with respect to the support stand in a first direction, and rotating through a second angle with respect to the support stand in a second direction different from the first direction;
wherein when the main body rotates with respect to the support stand in the first direction, the battery is parallel to the first edge; and when the main body rotates with respect to the support stand in the second direction, the battery is capable of switching between parallel to the first edge and parallel to the second edge.

13. The flat electronic device according to claim 12, wherein lengths of the first and second edges are different.

14. The flat electronic device according to claim 12, wherein the second direction is perpendicular to the first direction.

15. The flat electronic device according to claim 14, wherein the support stand further comprises a connecting portion connecting the battery and the rotation mechanism; the connecting portion defines at least one shaft hole; the main body comprises a positioning portion, the rotation mechanism comprises a base portion, and an accommodating portion protruding from the base portion, and at least shaft protruding from the accommodating portion; the shaft is inserted into the shaft hole such that the main body is capable of rotating with respect to the support stand in the first direction; and the base portion is rotatably received in the positioning portion such that the main body is capable of rotating with respect to the support stand in the second direction.

16. The flat electronic device according to claim 15, wherein the main body comprises a first surface on which the display screen is mounted, and a second surface opposite to the first surface; the positioning position is arranged on the second surface.

17. The flat electronic device according to claim 16, wherein the second surface is partially recessed to form a receiving portion for receiving the connecting portion.

18. The flat electronic device according to claim 17, wherein the receiving portion extends from the positioning portion, along the second surface, to the side of the first edge.

19. The flat electronic device according to claim 12, wherein the first angle is between 0 and 180 degrees, and the second angle is between 0 and 360 degrees.
